(19) United States
(12) Patent Application Publication
(10) Pub. No.: US 2005/0011442 A1
(43) Pub. Date: Jan. 20, 2005

(54) PLASMA PROCESSING MATERIAL RECLAMATION AND REUSE

(75) Inventors: Bomy A. Chen, Cupertino, CA (US); John A. Fitzsimmons, Poughkeepsie, NY (US); Vincent J. McGahay, Poughkeepsie, NY (US); James G. Ryan, Newtown, CT (US); Pavel Smetana, Poughkeepsie, NY (US)

Correspondence Address: HOFFMAN WARNICK & D'ALESSANDRO, LLC, 3 E-COMM SQUARE, ALBANY, NY, 12207, US

(73) Assignee: INTERNATIONAL BUSINESS MACHINES CORPORATION, Armonk, NY (US)

(21) Appl. No.: 10/604,058

(22) Filed: Jun. 24, 2003

(51) Int. Cl. C23C 16/00; H05H 1/24

(52) U.S. Cl. 118/715; 427/345; 427/569

(57) ABSTRACT

An integrated circuit plasma processing system, apparatus and method for reclaiming material, such as a plasma precursor and potentially useful components among their byproducts, from plasma-enhanced exhaust of a plasma process chamber for subsequent reuse in the chamber. The apparatus provides a recycle feedback loop for a plasma process chamber that provides the high purity materials necessary for microelectronic applications. Since the apparatus is in-situ, no byproducts that are not already present are possible. Accordingly, the apparatus guarantees purity of the recycled material. In addition to cost savings, the invention provides an environmentally friendly plasma process chamber and apparatus with very little production of waste.

### BACKGROUND OF INVENTION

1. Technical Field

The present invention relates generally to material reclamation, and more particularly, to plasma processing material reclamation and reuse.

2. Related Art

Manufacture of integrated circuits (ICs) by means of plasma-enhanced processing such as deposition and etch processes often involves the use of expensive precursors such as tungsten hexafluoride or tetra ethyl orthosilicate. The percentage of precursor exhausted from plasma process chambers, either in original form or in the form of byproducts of plasma-induced reactions, can be very high. For example, for plasma-enhanced chemical vapor deposition (PECVD) of WF6 for tungsten deposition, approximately 82% of the tungsten is exhausted. Exhausting such high percentages of material poses environmental issues and economic issues.

Relative to environmental issues, exhaust of such materials is generally to be avoided. Conventional approaches to addressing the environmental issues of this problem include implementing a scrubber to trap components of the exhaust for subsequent disposal or converting the exhaust into more environmentally friendly chemical species. Unfortunately, either approach generally results in a significant waste stream of non-recovered material.

In terms of economics, materials such as a precursor are usually very expensive. Accordingly, exhausting a high percentage of a precursor from plasma process chambers is very inefficient. In some cases, attempts to recover exhaust for subsequent recycling have been implemented. However, these approaches introduce impurities into the reclamation process, which destroys precursor purity and the ability to reuse the reclaimed precursor.

In view of the foregoing, there is a need in the art for a mechanism to reclaim material from plasma-enhanced exhaust for potential reuse.

### SUMMARY OF INVENTION

The invention includes an integrated circuit plasma processing system, apparatus and method for reclaiming material, such as a plasma precursor and potentially useful components among their byproducts, from plasma-enhanced exhaust of a plasma process chamber for subsequent reuse in the chamber. The apparatus provides a recycle feedback loop for a plasma process chamber that provides the high purity materials necessary for microelectronic applications. The apparatus is in-situ and does not introduce impurities into the reclaimed material. In addition to cost savings, the invention provides an environmentally friendly plasma process chamber and apparatus with very little production of waste.

A first aspect of the invention is directed to an apparatus for reclamation of material used in an integrated circuit plasma process chamber, the apparatus comprising: a first separator receiving plasma-enhanced exhaust from a process chamber, the first separator including a plurality of temperature zones, each temperature zone including a temperature control device and a collection vessel for collecting material that condenses in the respective temperature zone.

A second aspect of the invention is directed to an integrated circuit plasma processing system comprising: a process chamber for carrying out plasma-enhanced processing on a wafer; and a reclamation system including: a first separator receiving plasma-enhanced exhaust from the process chamber, the first separator including a plurality of temperature zones, each temperature zone including a collection vessel for collecting material that condenses in the respective temperature zone; a material processing unit coupled to an outlet of each collection vessel; and a material reuse unit coupled to each material processing unit.

A third aspect of the invention is directed to a method of reclaiming material used in integrated circuit plasma processing, the method comprising the steps of: exposing plasma-enhanced exhaust from a process chamber to a plurality of temperature zones, each temperature zone having a lower temperature than a preceding temperature zone; and collecting material that condenses in each respective temperature zone.

The foregoing and other features of the invention will be apparent from the following more particular description of embodiments of the invention.

### BRIEF DESCRIPTION OF DRAWINGS

The embodiments of this invention will be described in detail, with reference to the following figures, wherein like designations denote like elements, and wherein:

FIG. 1 shows an integrated circuit plasma processing system including a reclamation system according to the invention.

FIG. 2 shows a detail of a separator shown in FIG. 1.

FIG. 3 shows a cross-sectional view of a temperature zone of the separator of FIG. 2.

### DETAILED DESCRIPTION

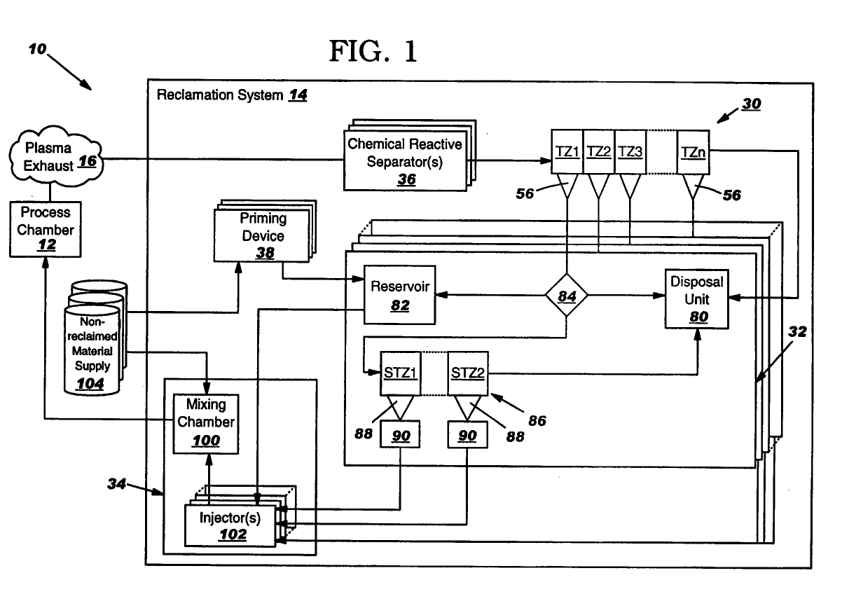

With reference to the accompanying drawings, FIG. 1 shows an integrated circuit (IC) plasma processing system 10 including a process chamber 12 and a reclamation (and reuse) system 14 according to the invention. Process chamber 12 may be any device for carrying out any now known or later developed plasma-enhanced processing. For example, plasma-enhanced chemical vapor deposition (PECVD) and/or reaction ion etching (RIE) on an IC wafer may be carried out in process chamber 12. Plasma-enhanced processing generally involves use of a carrier gas or diluent (e.g., a relatively inert gas such as nitrogen (N₂)) in combination with appropriate reactants. For example, one plasma-enhanced process for deposition of silicon dioxide (SiO₂) on a wafer can be accomplished by introduction of silane (SiH₄) and nitrous oxide (N₂O) into a nitrogen plasma at relatively low temperatures (i.e., <400 Å° C.). In another example, deposition of silicon dioxide (SiO₂) can be accomplished by introduction of tetra ethyl orthosilicate (TIOS) in an oxygen (O₂) plasma.

Plasma-enhanced exhaust 16 is output by process chamber 14. “Plasma-enhanced exhaust” 16 may include, in part, the carrier that is used to carry or react with a precursor, the precursor, any byproduct of a plasma-induced reactions and perhaps other byproduct(s). Since many plasma-enhanced precursors and byproducts are very expensive and in many cases environmentally unfriendly, it is advantageous to reclaim as much of them as possible. Reclamation system 14 provides an in-situ feedback loop to process chamber 12 that accomplishes this reclamation.

Reclamation system 14 may include a first, primary separator 30 for receiving plasma-enhanced exhaust 16 from process chamber 12, at least one material processing unit 32 coupled to primary separator 30, and a material reuse unit 34 coupled to each material processing unit 32. Reclamation system 14 may also optionally include at least one chemical reactive separator 36 and at least one priming device 38 (described below). Each chemical reactive separator 36 receives plasma-enhanced exhaust 16 prior to primary separator 30, and separates chemically reactive material from plasma-enhanced exhaust 16 based on the material's chemical reactivity. For example, a chemical reactive separator 36 may include magnesium turnings to capture fluorine, zinc turnings to capture oxygen, or other mechanisms to capture chemically reactive materials.

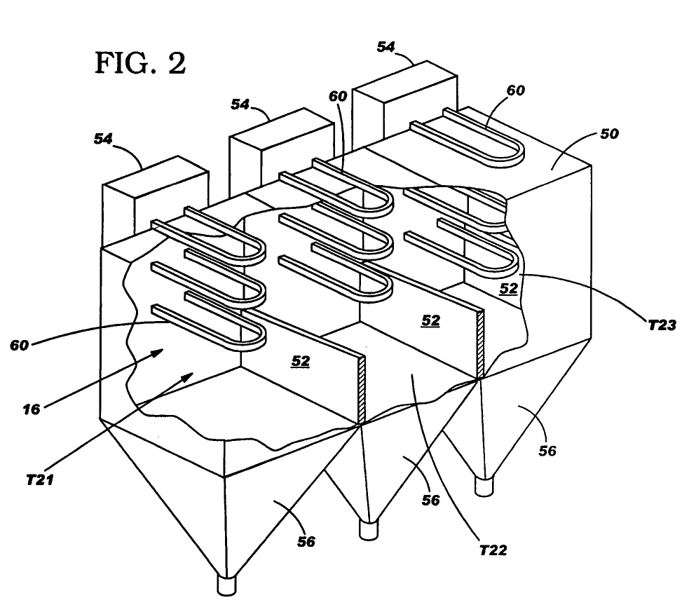

Primary separator 30 is provided to selectively separate out materials (not captured by chemical reactive separator 36 when provided) from plasma-enhanced exhaust 16. Primary separator 30 may include a plurality of temperature zones TZ1, TZ2, TZ3 â [symbol] TZn, where n is an integer, to condense materials out of plasma-enhanced exhaust 16 to accomplish this material separation. Referring to FIGS. 1 and 2, in one embodiment, primary separator 30 is provided as a separator chamber 50 including a series of temperature zones TZ, each separated by a baffle 52 to prevent remixing of materials. Each temperature zone TZ may include a temperature control device 54 and a collection vessel 56 for collecting material that condenses from plasma-enhanced exhaust 16 in the respective temperature zone TZ. Although separator chamber 50 is shown in a horizontal and straight orientation, it should be recognized that it can be, depending on space constraints, positioned horizontally, vertically and/or at some angle, and may be straight and/or curved. Alternatively, primary separator 30 may be implemented on already existing equipment, e.g., through the addition of temperature control devices 54 and collection vessels 56 to a pathway for plasma-enhanced exhaust 16.

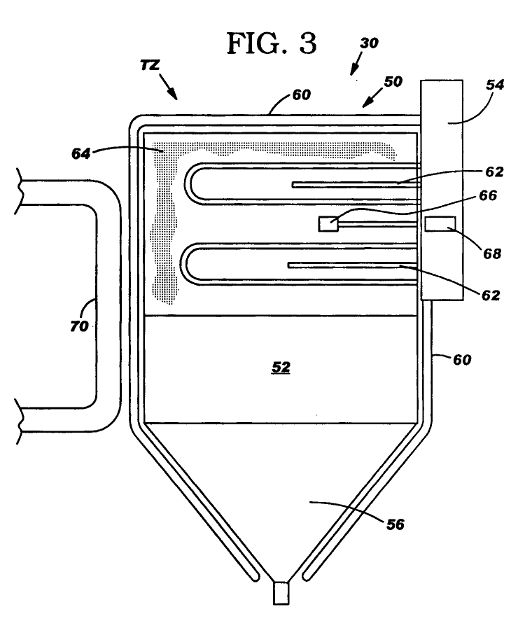

Referring to FIG. 3, a cross-sectional view of one embodiment of a temperature zone TZ is shown. Each temperature zone TZ includes a temperature control device 54 to set and maintain the zone (including collection vessel 56) at a condensing temperature of a selected material to be collected from plasma-enhanced exhaust 16 (FIG. 1). “Condensing temperature” may be any temperature that is below a boiling temperature of the selected material to be collected. A “selected material” may be any material, or combination of materials, that is/are to be reclaimed and is/are known to condense at the condensation temperature. In one embodiment, each temperature zone TZ(x) has a lower temperature than a preceding temperature zone TZ(x−1). That is, a warmest end of primary separator 30 receives plasma-enhanced exhaust 16 first. As a selected material condenses in a temperature zone TZ, the selected material collects in collection vessel 56. Each collection vessel is coupled to a respective material processing unit 32 (FIG. 1) for further processing, as described below. In one embodiment, each collection vessel 56 collects material by gravity feed. However, it should be recognized that other mechanisms are possible for material collection where necessary, e.g., vacuum feed, pumping, etc.

Each temperature control device 54 may take any form necessary to generate as uniform temperature as possible within a temperature zone TZ, and to control the condensation process of a specific material occurring therein. Temperature control device 54 may be provided with a number of temperature adjustment mechanisms. For instance, cooling can be provided by flowing coolants such as liquid nitrogen through a coil(s) or finger(s) 60 in and/or around separator chamber 50. Alternatively, heating may be provided by a heating element(s) 62 in and/or around separator chamber 50. Each collection vessel 56 may also be maintained at the condensing temperature by coil(s)/finger(s) 60 and/or heating element(s) 62.

As one with skill in the art will recognize, a variety of alternative configurations can be provided to establish uniform temperature within a temperature zone TZ. For example, the density, shape, occupied internal volume, material of cooling coil(s)/finger(s) 60 and/or heating element(s) 62 can be adjusted. Additionally, coil(s)/finger(s) 60 may be designed to variably retard plasma-enhanced exhaust 16 (FIG. 1) flow within separator chamber 50 in order to provide additional contact time to assure equilibrium. A uniform temperature within a temperature zone may also be enhanced by the use of a filler material 64. In one embodiment, filler material 64 is provided as a steel wool-like material to maintain temperature uniformity within temperature zone. Other examples may include filler material shaped as spheres (or beads), pins/screws, saddles, etc. Filler material 64 also may increase an area for a selected material to condense on, and impede the flow of plasma-enhanced exhaust 16 so that the contact time may be increased to maximize the gas equilibrium within a respective temperature zone TZ. As a result, filler material 64 enhances condensation and collection efficiency. The condensation process may also be modified by altering flow parameters of plasma-enhanced exhaust 16 (FIG. 1) such as volume, flow rate and/or introducing variations in filler material 64 makeup and/or density. Other modifications may also be provided such as gas flow restrictors (fixed or variable), a variation in baffle 52 design to increase surface area or retard flow, etc. Each temperature control device 54 may include a thermocouple sensor 66 and feedback system 68 to adjust the output of coil(s)/finger(s) 60 and/or heating element(s) 62. Although each temperature zone TZ has been shown with an independent temperature control device 54, it should be recognized that consolidation of all or part of temperature control devices may be possible.

Primary separator 30 may also be provided with a regeneration device 70 for using heat generated by the primary separator. Regeneration device 70 is used to direct material used in other processes to primary separator 30 for preheating to decrease the energy required to heat the material. For example, liquid gas such as liquid nitrogen that requires heating by a vaporizing heater (not shown) in order to vaporize into a usable gaseous form may be exposed to regeneration device 70 prior to the vaporizing heater.

Returning to FIG. 1, each material processing unit 32 includes: a disposal unit 80 for disposing of reclaimed, but unwanted material; a reservoir 82 for holding reclaimed and wanted material; and a directing valve 84 for selectively directing material to one of disposal unit 80 and reservoir 82. Directing valve 84 may be any now known or later developed mechanism for controlling the flow of a material, e.g., a computer controlled valve, which is received from a respective collection vessel 56. Disposal unit 80 is any mechanism capable of disposing of a material reclaimed by a respective temperature zone TZ that is not reusable. Disposal unit may include, for example, mechanism(s) for containing a material (e.g., a tank, a barrel, dumpster, etc.), an incinerator for burning material, scrubber, an atmospheric exhaust (stack, drain, etc.) or any other mechanism(s) now known or later developed for disposing of a material. Reservoir 82 may be any device capable of holding a selected material directed thereto (e.g., a tank, a barrel, etc.).

Optionally, each material processing unit 32 may also include a second separator 86 for further, higher stage separation of at least one selected material from material collected by a respective temperature zone TZ of primary separator 30. Second separator 86 may be configured substantially similar to primary separator 30, and may include at least one secondary temperature zone STZ1 having a respective temperature control device (not shown) and collection vessel 88. Each secondary temperature zone STZ has a temperature different than a respective preceding temperature zone TZ of primary separator 30 such that further separation of a material from plasma-enhanced exhaust 16 can be made. When second separator 86 is provided, directing valve 84 may direct material to one of disposal unit 80, reservoir 82 and the second separator. Output of collection vessel(s) 88 may be to an additional reservoir(s) or disposal unit(s) 90. Reservoir (s)/disposal unit(s) 90 are substantially similar to those described above.

Plasma-enhanced exhaust 16 exiting from reclamation system 14 (e.g., from primary separator 30 or secondary separator 86, if provided) may be sent to disposal unit 80 for appropriate disposal.

Material reuse unit 34 includes: a mixing chamber 100 for receiving material from at least one reservoir 82, 90, and an injector 102 coupled to each reservoir 82, 90. Each injector 102 selectively communicates material from a respective reservoir 82, 90 to mixing chamber 100. A non-reclaimed material supply 104 may also be coupled to mixing chamber 100 for supplying any number of fresh materials and/or modifying reagents thereto. Material supply 104 may include any number of supplies of fresh, unused material (e.g., a precursor and/or reactant material) used in process chamber 12 and/or any number of supplies of modifying reagents. A “modifying reagent” may be any material used to return a spent reactant to a chemical state similar to an original feedstock. One example modifying reagent is oxygen used to re-oxidize material to be injected in process chamber 12. Each injector 102 may be computer controlled and linked to a recipe system (not shown) of process chamber 12 in a fashion identical to that employed for conventional fresh material feeds. Mixing chamber 100 is coupled to process chamber 12 for supplying reclaimed material, perhaps combined with non-reclaimed material, to process chamber 12.

A priming device 38 may be provided for each reservoir 82, 90. Each priming device 38 is coupled to a respective reservoir 82 (and, although not shown for clarity, a respective reservoir 90) and to non-reclaimed material supply 104. Each priming device 38 includes any mechanism (s) necessary to insert a non-reclaimed material from non-reclaimed material supply 104 to a respective reservoir 82, 90 in a desired form. The material that priming device 38 receives may be the same as or different than the material in a respective reservoir 82, 90. For example, the material to be inserted may be the same as that in reservoir 82, 90, but may require processing (e.g., breaking down, condensation and/or other modification) into a more desirable feedstock prior to insertion a respective reservoir 82, 90. In another example, priming device 38 may insert any other material necessary such as a modifying reagent, reactant or additive to material in a respective reservoir 82, 90. Priming device(s) 38 may also provide a mechanism for “priming” reclamation system 14 where reclaimed material in reservoir(s) 82, 90 is of insufficient quantity, or may require additives, in order to start the system.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

1. An apparatus for reclamation of material used in an integrated circuit plasma process chamber, the apparatus comprising: a first separator receiving plasma-enhanced exhaust from a process chamber, the first separator including a plurality of temperature zones, each temperature zone including a temperature control device and a collection vessel for collecting material that condenses in the respective temperature zone.

2. The apparatus of claim 1, wherein each temperature zone has a lower temperature than a preceding temperature zone.

3. The apparatus of claim 1, further comprising a baffle between each temperature zone.

4. The apparatus of claim 1, further comprising a material processing unit coupled to an outlet of each collection vessel.

5. The apparatus of claim 4, wherein each material processing unit includes:
a disposal unit for disposing of material that is unreusable;
a reservoir for holding material that is reusable; and
a directing valve for directing material to one of the disposal unit and the reservoir.

6. The apparatus of claim 5, wherein each material processing unit further includes a second separator, the second separator including at least one secondary temperature zone having a temperature different than a respective preceding temperature zone of the first separator.
wherein each secondary temperature zone includes a secondary collection vessel for collecting material that condenses in the respective secondary temperature zone, and
wherein the directing valve directs material to one of the disposal unit, the reservoir and the second separator.

7. The apparatus of claim 4, further comprising a material reuse unit coupled to each material processing unit.

8. The apparatus of claim 7, wherein the material reuse unit includes:
a mixing chamber for receiving material from at least one reservoir, the mixing chamber coupled to the plasma process chamber; and
an injector coupled to each reservoir for selectively communicating material from a respective reservoir to the mixing chamber.

9. The apparatus of claim 8, further comprising a non-reclaimed material supply coupled to the mixing chamber.

10. The apparatus of claim 9, further comprising a priming device for inserting non-reclaimed material from the non-reclaimed material supply into the reservoir.

11. The apparatus of claim 1, further comprising a chemical reactive separator for receiving the plasma-enhanced exhaust prior to the first separator and separating chemically reactive material from the plasma-enhanced exhaust.

12. The apparatus of claim 1, further comprising a regeneration device for using heat generated by the first separator.

13. An integrated circuit plasma processing system comprising:
a process chamber for carrying out plasma-enhanced processing on a wafer; and
a reclamation system including:
a first separator receiving plasma-enhanced exhaust from the process chamber, the first separator including a plurality of temperature zones, each temperature zone including a collection vessel for collecting material that condenses in the respective temperature zone;
a material processing unit coupled to an outlet of each collection vessel; and
a material reuse unit coupled to each material processing unit.

14. The apparatus of claim 13, wherein each temperature zone has a lower temperature than a preceding temperature zone.

15. The apparatus of claim 13, wherein each material processing unit includes:
a disposal unit for disposing of unwanted material;
a reservoir for holding wanted material; and
a directing valve for directing material to one of the disposal unit and the reservoir.

16. The apparatus of claim 15, wherein each material processing unit further includes a second separator, the second separator including at least one secondary temperature zone having a temperature different than a respective preceding temperature zone of the first separator,
wherein each secondary temperature zone includes a secondary collection vessel for collecting material that condenses in the respective secondary temperature zone, and
wherein the directing valve directs material to one of the disposal unit, the reservoir and the second separator.

17. The apparatus of claim 13, wherein the material reuse unit includes:
a mixing chamber for receiving material from at least one reservoir, the mixing chamber coupled to the process chamber;
an injector coupled to each reservoir for selectively communicating material from a respective reservoir to the mixing chamber; and
a non-reclaimed material supply coupled to the mixing chamber.

18. The apparatus of claim 13, further comprising a chemical reactive separator for receiving exhaust prior to the first separator and separating chemically reactive material from the exhaust.

19. A method of reclaiming material used in integrated circuit plasma processing, the method comprising the steps of:
exposing plasma-enhanced exhaust from a process chamber to a plurality of temperature zones, each temperature zone having a lower temperature than a preceding temperature zone; and
collecting material that condenses in each respective temperature zone.

20. The method of claim 19, further comprising reusing the collected material.
